(19) United States
(12) Patent Application Publication
(10) Pub. No.: US 2011/0074380 A1
(43) Pub. Date: Mar. 31, 2011

(54) ELECTRIC CONDUCTION PAD AND MANUFACTURING METHOD THEREOF

(75) Inventor: Byung-Ok Jeon, Seoul (KR)

(73) Assignee: SILVERAY CO., LTD., Gimhaeisi-Gyeongsangnam-do (KR)

(21) Appl. No.: 12/994,086

(22) PCT Filed: May 25, 2009
(86) PCT No.: PCT/KR09/02761

§ 371 Date: Nov. 22, 2010

(30) Foreign Application Priority Data
May 28, 2008 (KR) 10-2008-0050545
Dec. 16, 2008 (KR) 10-2008-0128928
May 20, 2009 (KR) 10-2009-0043932

(51) Int. Cl. H02J 4/00; H05K 1/00; H05K 1/09; H01R 43/16; H05B 3/10

(52) U.S. Cl. 323/318; 174/250; 174/251; 29/874; 219/553

(57) ABSTRACT

The present invention relates to electric conduction pads and a method for manufacturing the same, and more particularly, to an electric conduction pad having elastic properties while enabling heat emission, passage of electric current and transmission of electrical signals, using an electrically conductive wire material, as well as a method for manufacturing the same. The electric conduction pad of the present invention comprises: a stretchable planar pad; and at least one conductive wire aligned in a zig-zag pattern on the pad to pass electric current supplied from a power source or emit heat by the same.

### TECHNICAL FIELD

The present invention relates to electric conduction pads and a method for manufacturing the same, and more particularly, to an electric conduction pad having elastic properties while enabling heat emission, passage of electric current and transmission of electrical signals, using an electrically conductive wire material, as well as a method for manufacturing the same.

### BACKGROUND

Knitted or woven fabrics used in production of garments and accessories are generally made from natural or man-made fiber yarns, include various kinds of fabrics and have inherent properties and features. Such fabrics having heat retention, water absorption, elastic properties, etc., achieve desired functions when completely fabricated into garments, and the like.

However, as industrial society becomes highly advanced and complicated, modem people demand garments with improved performance in addition to conventional functions thereof such as heat retention properties to keep out the cold, elastic properties to ensure sufficient range of motion and favorable water absorption to absorb sweat.

For instance, a garment enabling passage of electric current to which a variety of electronic devices are attached for convenient use thereof, an intelligent garment capable of emitting heat or having cooling effects, which is thin and lightweight and may be wearable in all seasons, and the like, is currently expected.

Under such circumstances, so as to satisfy the foregoing social requirements in textile applications and lead the future of the same, much research and development as well as extensive effort is recently being conducted. As a result of such studies, some smart clothes are produced and commercially available in the market.

Representative examples of such smart clothes may include heat emitting clothes such as a heat vest widely used for leisure, a garment with built-in electronic device enabling convenience in use of the electronic device, for example, MP3.

A heat emitting garment may be manufactured by forming a heating wire using carbon fiber yarns or copper wires, stitching a planar heating element made of the formed heating wire inside the garment or placing the same in an alternative pouch, and allowing heat generation based on resistant heat of electric current supplied from a power supply unit.

However, such a heat emitting garment has a planar heating element without elasticity, thus being limitedly used for some part of the garment corresponding to back and/or belly of the human, on which elastic properties are relatively less required. Therefore, the heat emitting garment may be restrictedly applied to, for example, a specific garment requiring a relatively small range of motion such as a fishing vest. In addition, since the heat emitting garment does not have elasticity and cannot ensure sufficient durability, this is currently not employed in various applications requiring a wide range of motion including, for example, diving suits, working clothes, battle dress, sports wear, and so forth.

Moreover, a garment with a built-in electronic device is fabricated by preparing an operation button of the electronic device on a Velcro fastener of the garment and detachably fixing the button to a sleeve thereof, and placing another operation button, a power supply and conductive wires for transfer of current and/or electrical signals to the electronic device on an inner side of the garment.

However, such a garment with built-in electronic device having the conductive wires inside the garment entails poor wear convenience and the conductive wires and/or the operation button fixed inside the garment should be removed during washing, in turn causing significant difficulties in using these elements. Furthermore, since the conductive wires built in the garment have less elasticity, the garment may not have favorable motion and durability. Accordingly, such garment is still not practically applied, although experimental clothes and/or sample clothes have been currently developed.

### SUMMARY

The present invention is directed to solving conventional problems described above and an object of the present invention is to provide an electric conduction pad having elastic properties while enabling heat emission and passage of electric current, which is fabricated using an electrically conductive wire material without elasticity, thus ensuring sufficient range of motion and durability thereof, as well as a method for manufacturing the same.

A second object of the present invention is to provide an electric conduction pad with improved durability and strength, fabricated using an electrically conductive wire material without elasticity, so as to exhibit elastic properties when external force is applied thereto, while preventing friction and/or damage of the same.

A third object of the present invention is to provide an electric conduction pad with improved durability and strength, fabricated using an electrically conductive wire material without elasticity, so as to exhibit elastic properties when external force is applied thereto and prevent friction and/or damage of the same even without an alternative protective pad, as well as a method for manufacturing the same.

A fourth object of the present invention is to provide an electric conduction pad having electrical conduction, elastic properties, durability and safety, reduced thickness and weight which are sufficient to ensure favorable wearing sensation and motion, and improved productivity, as well as a method for manufacturing the same.

In order to accomplish the foregoing purposes of the present invention, there is provided an electric conduction pad, including: a stretchable planar pad; and at least one conductive wire aligned in a zig-zag pattern on the pad to pass electric current supplied from a power source or emit heat by the same.

In order to accomplish the foregoing purposes of the present invention, there is provided a method for manufacturing an electric conduction pad, comprising: fabricating a planar pad using at least one elastic fiber yarn as wefts and warps; and providing a conductive wire on the planar pad by aligning the conductive wire in a zig-zag pattern on the top of the planar pad and binding a part, which is adjacent to both curved sides of the conductive wire, to the planar pad.

In order to accomplish the foregoing purposes of the present invention, there is provided a method for manufacturing an electric conduction pad, comprising: fabricating a planar pad using at least one elastic fiber yarn as wefts and warps; and providing a conductive wire on the planar pad by aligning the conductive wire in a zig-zag pattern on the top of the planar pad and inserting a part, which is adjacent to both curved sides of the conductive wire, between the wefts and warps to be bound thereto.

The present invention also provides a method for manufacturing an electric conduction pad, including: fabricating a planar pad using elastic fiber yarns as wefts and warps; providing at least one conductive wire on the pad by aligning the conductive wire in a zig-zag pattern over the fabricated pad and binding a part adjacent to both curved parts of the conductive wire to the planar pad; and preparing an elastic loop into which the conductive wire is inserted, so as to secure the conductive wire to the pad.

There is provided another method for manufacturing an electric conduction pad, including: fabricating a planar pad using elastic fiber yarns as the weft and warp; and providing at least one conductive wire on the pad by aligning the conductive wire in a zig-zag pattern over the fabricated pad and binding a part adjacent to both curved parts of the conductive wire to the planar pad, wherein multiple hook holes are formed on the planar pad during fabrication thereof, so as to insert the conductive wire therein.

In order to accomplish the foregoing purposes of the present invention, there is provided an electric conduction pad in a band form, comprising: a plurality of elastic wires aligned in a length direction; at least one conductive wire woven and aligned in a zig-zag pattern on the elastic wires; and a protective fiber yarn woven on the elastic wires such that the protective fiber yarn is aligned in a zig-zag pattern adjacent to the conductive wire.

In order to accomplish the foregoing purposes of the present invention, there is provided an electric conduction pad, comprising: a base formed in a planar shape; and at least one conductive wire woven and aligned in a zig-zag pattern on the planar base, wherein the planar base has a flow space inside a part, at which both curved sides of the conductive wire is positioned, so as to flow the curved parts through the flow space.

In order to accomplish the foregoing purposes of the present invention, there is provided a method for manufacturing an electric conduction pad, comprising: providing a fiber yarn as wefts and warps so as to form a planar base; simultaneously providing at least one conductive wire as well as the wefts and warps to be woven in a zig-zag pattern on the planar base; and fabricating the planar base using the wefts, warps and conductive wire, which are provided during provision of the fiber yarn and during provision of the conductive wire, respectively, by a weaving process, wherein a flow space is formed inside a part, at which both curved sides of the conductive wire are positioned, during the weaving process so as to flow the curved parts through the flow space.

According to the electric conduction pad and the method for manufacturing the same of the present invention, a planar heating element or conductive element having elasticity may be fabricated using an electrically conductive wire without elasticity, such as a carbon fiber yarn, a copper wire, etc. Therefore, if a smart garment requiring convenience in motion or an electric heating device is manufactured using such a conductive element, a desired range of motion may be ensured, in turn remarkably enhancing advantages in use as well as durability.

Also, according to the foregoing conduction pad of the present invention, a planar heating element or conductive element having elasticity may be fabricated using an electrically conductive wire without elasticity such as a carbon fiber yarn, a copper wire, etc. Especially, a protective fiber yarn is additionally used to protect the conductive wire, thus preventing friction or damage thereof in advance. Therefore, when the above conduction pad is applied to smart clothes requiring convenience in motion or an electric heating device, features of the pad such as durability, strength and safety may be noticeably improved.

Furthermore, according to the foregoing conduction pad of the present invention, a planar heating element or conductive element having elasticity may be fabricated using an electrically conductive wire without elasticity such as a copper wire wherein a flow space is formed in a curved part of the conductive wire. Therefore, even if a protective pad is not additionally used to manufacture an electric conduction pad, friction or damage of the conductive wire is prevented, thus noticeably enhancing durability and safety of the conduction pad.

### BRIEF DESCRIPTION OF DRAWINGS

The above and other objects, features and other advantages of the present invention will be more clearly understood from the following detailed description taken in conjunction with the accompanying drawings, in which:

FIG. 1a illustrates the technical concept of an electric conduction pad according to the present invention;

FIGS. 1b and 1c are perspective views illustrating the construction of a conductive wire used for the conduction pad according to the present invention;

FIG. 2 is a cross-sectional view illustrating main parts of an electric conduction pad according to a first embodiment of the present invention;

FIG. 3 illustrates a process of manufacturing the conduction pad according to the first embodiment of the present invention;

FIG. 4 illustrates a first modification of the conduction pad according to the first embodiment of the present invention;

FIG. 5 illustrates a second modification of the conduction pad according to the first embodiment of the present invention;

FIG. 6 illustrates a third modification of the conduction pad according to the first embodiment of the present invention;

FIG. 7 illustrates a fourth modification of the conduction pad according to the first embodiment of the present invention;

FIG. 8 is a cross-sectional view illustrating main parts of an electric conduction pad according to a second embodiment of the present invention;

FIG. 9 is a cross-sectional view illustrating main parts of an electric conduction pad according to a third embodiment of the present invention;

FIG. 10 illustrates an electric conduction pad according to a fourth embodiment of the present invention;

FIG. 11 is a schematic view illustrating an electric conduction pad according to a fifth embodiment of the present invention;

FIG. 12 is a cross-sectional view taken along lines A-A shown in FIG. 11;

FIG. 13a is a plan view illustrating the electric conduction pad according to the fifth embodiment of the present invention;

FIG. 13b illustrates one modification of the electric conduction pad according to the fifth embodiment of the present invention;

FIG. 13c is an enlarged view of part B shown in FIG. 13b;

FIG. 14a is a plan view illustrating an electric conduction pad according to a sixth embodiment of the present invention;

FIG. 14b illustrates one modification of the electric conduction pad according to the sixth embodiment of the present invention;

FIG. 15a is a plan view illustrating an electric conduction pad according to a seventh embodiment of the present invention;

FIG. 15b is a plan view illustrating one modification of the electric conduction pad according to the seventh embodiment of the present invention;

FIG. 15c is a plan view illustrating another modification of the electric conduction pad according to the seventh embodiment of the present invention;

FIG. 16 is a perspective view explaining a technical concept of an electric conduction pad according to an eighth embodiment of the present invention;

FIG. 17a is a perspective view illustrating the electric conduction pad according to the eighth embodiment of the present invention;

FIG. 17b is a schematic cross-sectional view illustrating a cross section taken along lines A-A shown in FIG. 17a, so as to describe in detail the electric conduction pad according to the eighth embodiment of the present invention;

FIG. 18 is a plan photograph practically showing the electric conduction pad according to the eighth embodiment of the present invention;

FIG. 19 is a partially cut-away plan photograph practically showing main parts of the conduction pad shown in FIG. 18;

FIG. 20a is a perspective view showing a first example of a conductive wire applied to the electric conduction pad according to the eighth embodiment of the present invention;

FIG. 20b is a perspective view showing a second example of a conductive wire applied to the electric conduction pad according to the eighth embodiment of the present invention;

FIG. 20c is a perspective view showing a third example of a conductive wire applied to the electric conduction pad according to the eighth embodiment of the present invention;

FIG. 20d is a perspective view showing a fourth example of a conductive wire applied to the electric conduction pad according to the eighth embodiment of the present invention;

FIG. 21 is a perspective view and a partially enlarged view illustrating a first modification of the electric conduction pad according to the eighth embodiment of the present invention;

FIG. 22 is a perspective view and a partially enlarge view illustrating a second modification of the electric conduction pad according to the eighth embodiment of the present invention;

FIG. 23 is a perspective view illustrating a third modification of the electric conduction pad according to the eighth embodiment of the present invention;

FIG. 24 is a perspective view illustrating a fourth modification of the electric conduction pad according to eighth embodiment of the present invention;

FIGS. 25a and 25b are perspective views illustrating a fifth modification of the electric conduction pad according to the eighth embodiment of the present invention; and

FIG. 26 is a flow diagram explaining a process of manufacturing an electric conduction pad according to one embodiment of the present invention.

### DETAILED DESCRIPTION OF EXEMPLARY EMBODIMENTS

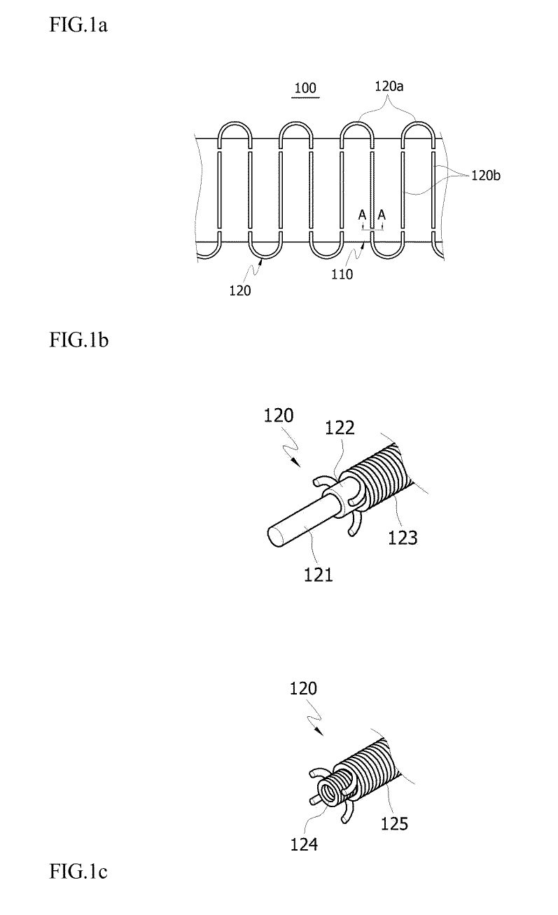

Hereinafter, preferred embodiments of the present invention will be described in detail in conjunction with accompanying drawings, especially, FIGS. 1a to 10. Referring to FIGS. 1a to 10, the same reference numbers are given for the same constitutional elements. Conventional technical configurations and functional effects thereof, which are easily conceived or understood by persons having ordinary skill in the related art, will be briefly described or omitted from detailed description. Instead, the foregoing inventive drawings may substantially illustrate subject matters relating to the present invention.

FIG. 1a illustrates the technical concept of an electric conduction pad according to the present invention; and FIGS. 1b and 1c are perspective views illustrating the construction of a conductive wire used for the electric conduction pad according to the present invention.

As shown in FIG. 1a, an electric conduction pad 100 of the present invention includes a stretchable planar pad 110 and at least one conductive wire 120 which is aligned in a zig-zag pattern on the pad 110.

Such a conductive wire 120 may comprise a power supply cable to pass electric current supplied from a power supply unit or a heating wire to emit resistant heat by power supplied from the power supply unit. The conductive wire 120 may comprise only the power supply cable or the heating wire or otherwise, have a combination thereof, according to use or purpose of the conduction pad 100.

The conductive wire 120 may comprise other various wire materials without limitation thereof, so far as these can pass electric current or emit heat. For instance, as shown in FIG. 1b, a conductive cord 121 made of linear material, an insulation film 122 coated on an outer side of the conductive cord, and a skin layer 123 formed by knitting or weaving a fiber yarn 111 around an outer side of the insulation film. Here, the skin layer 123 has a knitted form such that multiple fiber yarns 111 are woven around the outer side of the insulation film 122.

The conductive cord 121 may be formed using at least one of electrically conductive wires such as carbon fiber yarns, single-stranded metal wires, combined metal micro-wires, fiber yarns containing conductive materials, etc.

An alternative example of the conductive wire 120, as shown in FIG. 1c, comprises a linear element that includes a conductive cord 124 formed by winding a metal wire having a size in micrometer units (a diameter of 1 to 100 μm) in a spring shape and a skin layer 125 formed by knitting a fiber yarn 111 over the outer side of the conductive cord 124.

The planar pad 110 is fabricated by knitting or weaving elastic fiber yarns 111 used as wefts 112 and warps 113 (although such knitting and weaving processes are distinguishable from each other in textile applications, the present invention commonly uses these terms to refer to fabrication of a cloth using the fiber yarn 111, for brevity). In this regard, the pad 110 may have a wide range of width and length according to use and purpose thereof. For instance, the pad 110 may be fabricated in a band shape having a small width, in turn being applicable to specific parts of smart clothes or some goods with relatively a small width (i.e., a belt, a bracelet, a knee protector, etc.).

The fiber yarn 111 used for the pad 110 may be a spandex yarn having high elasticity and strength among commercially available fiber yarns. In this case, the entire fiber yarn 111 used for fabrication of the pad 110 may comprise the spandex yarn alone or a combination of the same with a typical fiber yarn.

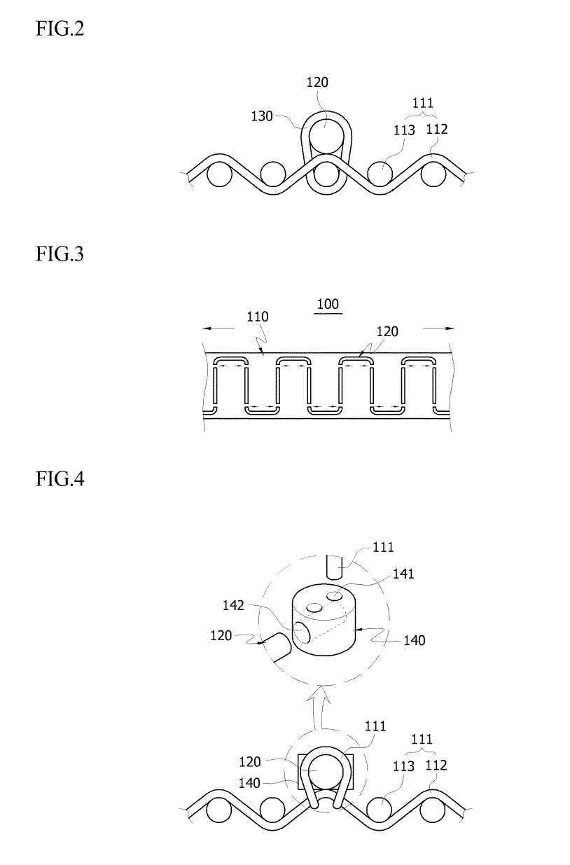

FIG. 2 illustrates main parts of an electric conduction pad according to a first embodiment of the present invention, which is a schematic cross-sectional view taken along lines A-A shown in FIG. 1 to show binding of the conductive wire 120 with the fiber yarn 111. FIG. 3 illustrates a process of manufacturing the electric conduction pad according to the first embodiment of the present invention.

Referring to FIG. 2, the electric conduction pad according to the first embodiment of the present invention will be described in detail. More particularly, the electric conduction pad 100 comprises a pad 110 and a conductive wire 120 placed on the pad 110. The conductive wire 120 is aligned in a zig-zag pattern on the top of the pad 110 and a static fiber yarn 130 is additionally backstitched at both sides of the conductive wire 120 in a width direction, to be bound to the pad 110.

When the conductive wire 120 is fixed by the additional static fiber yarn 130 instead of wefts 112 or warps 113 used for fabrication of the pad 110, the static fiber yarn 130 should be bound on the pad 110 while pulling the pad 110 in a length direction, so as to bind the conductive wire 120 to the pad 110, as shown in FIGS. 2 and 3. The major reason of such fixation of the conductive wire 120 while pulling the pad 110 is that, if the static fiber yarn 130 is backstitched without pulling the pad 110, a part of the pad 110 corresponding to the backstitched part is not stretched and the conductive wire 120 is also not smoothly stretchable.

Meanwhile, the conductive wire 120 is aligned in a zig-zag pattern, as described above. More preferably, the conductive wire may be aligned in a wave form such as pulse wave, sine wave, etc.

The static fiber yarn 130 is preferably fixed to both sides of a linear part 120b adjacent to both curved sides 120a of the conductive wire 120. As such, when backstitching the static fiber yarn 130 to both sides of the linear part adjacent to the curved sides 120a, the static fiber yarn 130 does not prevent stretching of the curved sides 120a while constantly maintaining alignment of the conductive wire 120.

FIG. 4 illustrates a first modification of the electric conduction pad according to the first embodiment of the present invention.

Referring to FIG. 4, the conduction pad further includes a guide member 140 on a site at which the conductive wire 120 is bound on the pad 110 and, through the guide member, the conductive wire 120 is combined with the pad 110, so as to prevent damage of the pad 110 during stretching.

Such a guide member 140 generally comprises a ball or button type element, a coupling hole 141 stitched to the pad 110, through which the fiber yarn 111 is inserted, and a coupler having a sliding hole 142 through which the conductive wire 120 is inserted and slidably moved therein. The coupling hole 141 may be formed not to intersect the sliding hole 142 as possible, so as to prevent the coupling hole from interfering with sliding of the conductive wire 120.

The guide member 140 may contain at least one selected from anion generating materials, sterile materials, aromatic materials and luminous materials.

The anion generating materials may include at least one selected from tourmaline, chitosan powder, tourmaline powder and loess powder. The sterile materials may include at least one selected from silver particles and charcoal powder. The aromatic materials may include agalloch.

Especially, when the guide member 140 contains the anion generating material, the conductive wire 120 consisting of a heating wire increases a temperature, in turn raising a temperature of the pad 110 and emitting anions in large quantities beneficial to the human body.

FIG. 5 illustrates a second modification of the electric conduction pad according to the first embodiment of the present invention. As shown in this figure, the conduction pad 110 further includes a temperature sensor 150 electrically connected to the conductive wire 120 so as to detect the heating temperature of the conduction pad 110.

Additionally, the conduction pad 100 further includes a plurality of LEDs 160 electrically connected to the conductive wire 120.

As such, if a garment such as a heat vest is manufactured using the electric conduction pad 100 equipped with the temperature sensor 150, detected signals applied from the temperature sensor enable control of the heating temperature.

When the conduction pad 100 includes an LED 160, light emission of the LED may be efficiently used in various applications requiring significant notice and/or discrimination such as working clothes, stage costume, emergent refuge clothes, etc.

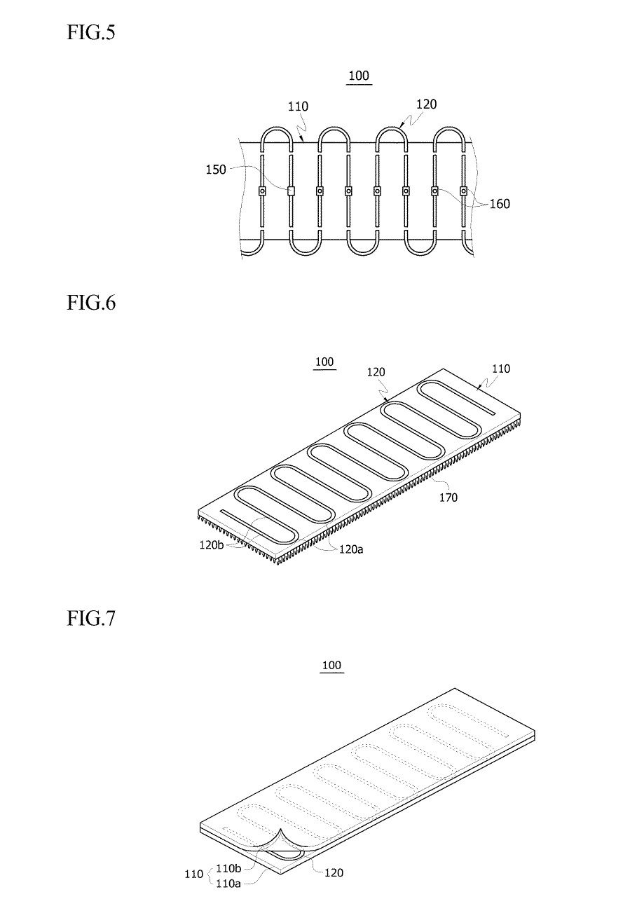

FIG. 6 is a perspective view illustrating a third modification of the conduction pad according to the first embodiment of the present invention.

Referring to FIG. 6, the planar pad 110 has a Velcro fastener 170 so as to attach or detach the conduction pad 100 from a desired place if it is necessary. That is, a protrusion (in general, ‘a male protrusion’ of the Velcro fastener, which is protruded in a form of wedge) and a hook ring (in general, ‘a female loop’ which has a ring shape) are provided on the top or bottom of the pad 110 to form the Velcro fastener. The male protrusion may be detachably secured to the hook ring of the Velcro fastener.

FIG. 7 is a perspective view illustrating a fourth modification of the conduction pad according to the first embodiment of the present invention.

As shown in FIG. 7, the conduction pad 100 according to the fourth modification comprises a stretchable planar pad 110 and at least one conductive wire 120 aligned in a zig-zag pattern on the planar pad 110. Here, the planar pad 110 has a bottom planar fabric part 110a fabricated using wefts 112 and warps 113 and a top planar fabric part 110b fabricated on the bottom fabric part 110a using the wefts 112 and warps 113.

The conductive wire 120 is provided in a zig-zag pattern above the bottom fabric part and both sides of the conductive wire in a width direction are repeatedly backstitched using the wefts 112 or warps 113 used for fabrication of the top fabric part, in turn being fixed thereto. At the same time, the conductive wire 120 is interposed between the top fabric part 110b and the bottom fabric part 110a.

The foregoing conduction pad 100 has pads 110 on upper and lower sides of the conductive wire 120. Therefore, since the conductive wire 120 is not directly in contact with the human body, fabric household goods such as smart clothes or floor cushions may be manufactured without a lining of an alternative finishing cloth.

Hereinafter, an electric conduction pad 100 according to second to fourth embodiments of the present invention will be described in detail. The foregoing modifications of the first embodiment may be duly applied to these second to fourth embodiments, although detailed description thereof is omitted.

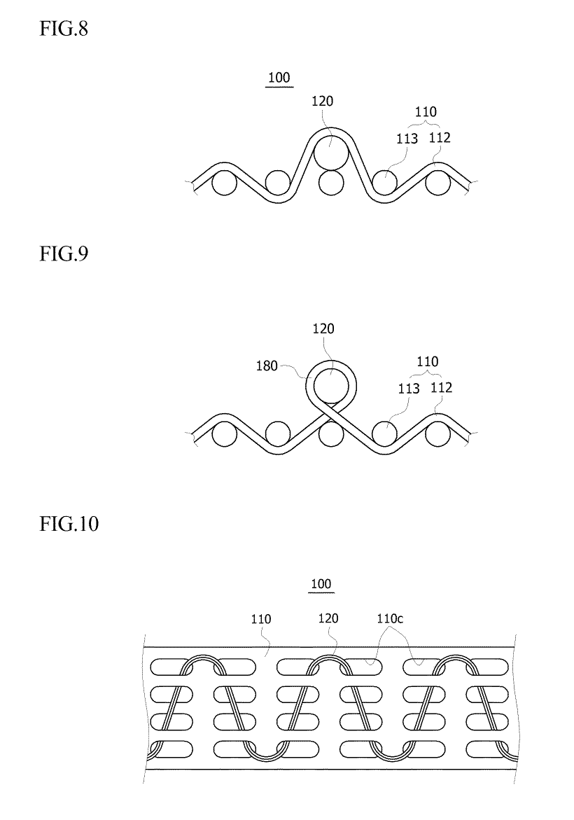

FIG. 8 illustrates main parts of the conduction pad according to the second embodiment of the present invention, which is a schematic cross-sectional view taken along lines A-A so as to show combination of the conductive wire 120 and a fiber yarn 111.

As shown in FIG. 8, the conduction pad 110 according to the second embodiment of the present invention comprises a stretchable planar pad 110 and at least one conductive wire 120 aligned in a zig-zag pattern on the pad 110. Both sides adjacent to a curved part 120a of the conductive wire 120 in a width direction are repeatedly bound using the wefts 112 and warps 113 used for fabrication of the pad 110. That is, the conductive wire 120 is inserted and bound between the weft 112 and the warp 113 during manufacture of the pad 110 or after completing the same.

As such, when the conductive wire 120 is inserted between the weft 112 and the warp 113 used for fabrication of the pad 110 and combined with the same, the conductive wire 120 is inter-working with the weft and warp elongated by tensile strength applied to the pad 110, thus being stretched. Therefore, even when the conductive wire is bound to the pad without pulling the pad 110, it is possible to ensure sufficient elasticity and durability of the conduction pad. Accordingly, a backstitching process using an alternative static fiber yarn 130 described in the foregoing first embodiment is not required, thus enabling the manufacture of an electric conduction pad to be more easily conducted.

FIG. 9 illustrates main parts of the electric conduction pad according to a third embodiment of the present invention, which is a schematic cross-sectional view taken along lines A-A shown in FIG. 1 so as to show combination of the conductive wire 120 and the fiber yarn 111.

As shown in FIG. 9, the conduction pad 100 according to the third embodiment of the present invention comprises a stretchable planar pad 110 and at least one conductive wire 120 aligned in a zig-zag pattern on the pad 110. A part of the pad 110, to which the conductive wire 120 is fixed, has an elastic loop 180 and the conductive wire 120 is inserted into the loop 180 and bound to the pad.

As shown in FIG. 9, the elastic loop 180 may be formed during fabrication of the pad 110 using the fiber yarn 111 or otherwise, by backstitching or coupling the loop 180 to the pad 110 as an alternative elastic loop 180 is formed.

If the conductive wire 120 is inserted into the elastic loop 180, the conductive wire 120 is stretchable while sliding along the elastic loop, as the pad 110 is elongated. As a result, elongation may be satisfactory owing to decrease in friction.

FIG. 10 illustrates an electric conduction pad 100 according to a fourth embodiment of the present invention.

As shown in FIG. 10, the conduction pad 100 according to the fourth embodiment of the present invention comprises a stretchable planar pad 110 and at least one conductive wire 120 aligned in a zig-zag pattern on the pad 110. The pad 110 has a plurality of hook holes 110c punctured on a surface of the pad and the conductive wire 120 is inserted into these hook holes 110c in a zig-zag pattern and bound to the pad.

Each hook hole may be a slot hole formed in an elongation direction of the pad 110, so as to ensure desired mobility and flexibility of the conductive wire 120.

Hereinafter, a method for manufacturing an electric conduction pad 100 of the present invention will be described in detail.

More particular, a method of manufacturing the electric conduction pad 100 according to the first embodiment of the present invention comprises: fabricating a planar pad 110 using elastic fiber yarns 111 as wefts 112 and warps 113; and providing a conductive wire by aligning the conductive wire 120 in a zig-zag pattern on a surface of the fabricated pad 110 and binding a part adjacent to both curved sides of the conductive wire 120 to the pad 110.

The fabrication of the pad is to provide the planar pad 110 using an elastic fiber yarn 111 such as a spandex yarn as the weft 112 and warp 113, and is performed using a typical weaving machine used in textile weaving industries.

The provision of the conductive wire may be performed by binding the conductive wire to the pad 110 using an alternative static fiber yarn 130, after the fabrication of the pad was completed to produce the pad 110. Here, so as to provide the conductive wire, a process of pulling the pad 110 in the alignment direction of the conductive wire 120 is required as shown in FIG. 3. In addition, the static fiber yarn 130 is not either the weft 112 or the warp 113 used for fabrication of the pad 110. Accordingly, when the static fiber yarn is bound to the pad 110 without pulling the pad 110, a part of the pad 110 at which the static fiber yarn 130 is backstitched cannot be elongated, in turn preventing the conductive wire 120 from smoothly stretching. Consequently, the provision of the conductive wire is preferably executed during elongation of the pad 110.

A binding site of the static fiber yarn 130 is desirably determined on a linear part adjacent to both curved sides of the conductive wire 120, so as to stretch the conductive wire 120 while stably maintaining alignment of the conductive wire 120 during elongation of the pad 110.

The provision of the conductive wire 120 is conducted using the static fiber yarn 130 during fabrication of the pad 110, so as to bind the conductive wire 120 to the pad 110 while fabricating the same.

In other words, the provision of the conductive wire is performed by aligning the conductive wire 120 in a zig-zag pattern on a site at which the pad 110 is fabricated, so as to enable a part adjacent to both curved sides of the conductive wire 120 to be stitched to the pad 110, during fabrication of the planar pad 110 using the elastic fiber yarn 111 as the weft 112 and warp 113 to form the planar pad.

In this case, the planar pad 110 should be fabricated by applying tensile force to the fiber yarn 111 since the static fiber yarn 130 is not either the weft 112 or the warp 113 used for fabrication of the pad 110 and, if the static fiber yarn 130 is bound to the pad without elongating the pad, sufficient elasticity and durability of the conductive wire 120 as well as the pad 110 cannot be attained.

As shown in FIG. 7, the inventive method for manufacturing the electric conduction pad may further include a process of forming an additional pad, so as to provide pad layers on inner and outer sides of the conductive wire 120.

The process for formation of the additional pad is conducted to form an additional pad layer (a top fabric 110b in FIG. 7) using an elastic fiber yarn 111, so as to cover a top surface of the electric conduction pad 100 including the conductive wire 120 wherein the additional pad layer may be prepared separately, then, attached to the conduction pad 100 or otherwise, may be formed while fabricating the planar pad 110 using the elastic fiber yarn 111.

As shown in FIG. 6, the method for manufacturing the electric conduction pad according to the present invention further includes a process of forming a Velcro fastener comprising preparation of a protrusion or a hook ring of the Velcro fastener on a top or bottom surface of the pad 110. Here, the Velcro fastener 170 may be prepared separately, then, attached to the conduction pad 100 or otherwise, may be formed while fabricating the planar pad 110.

Referring to FIG. 8, a method for manufacturing an electric conduction pad 100 according to a second embodiment of the present invention comprises: fabricating a planar pad 110 using elastic fiber yarns 111 as wefts 112 and warps 113; and providing a conductive wire on the planar pad by aligning the conductive wire 120 in a zig-zag pattern on a surface of the pad 110 and inserting a part adjacent to both curved sides 120a of the conductive wire 120 between the weft 112 and the warp 113 used for fabrication of the planar pad 110, thus being bound to the pad 110.

In this case, the provision of the conductive wire is conducted by providing the conductive wire 120 during fabrication of the pad 110 and inserting the same between the weft 112 and the warp 113, thus being bound to the pad 110.

Alternatively, the provision of the conductive wire may be conducted by inserting the conductive wire 120 between the weft 112 and the warp 113 after fabrication of the pad 110, thus being bound to the pad.

Referring to FIG. 9, a method for manufacturing an electric conduction pad 100 according to a third embodiment of the present invention comprises fabrication of a pad and provision of a conductive wire and further includes a process of forming an elastic loop 180 on the pad 110, into which the conductive wire 120 is inserted.

Such formation of the elastic loop is preferably conducted while fabricating the pad 110, enabling simultaneous formation of the pad 110 and the loop. That is, a process for formation of a ring type elastic loop 180 may be embodied using the weft 112 or warp 113 used for fabrication of the pad 110.

In addition, referring to FIG. 10, a method for manufacturing an electric conduction pad 100 according to a fourth embodiment of the present invention comprises fabrication of a pad and provision of a conductive wire, wherein a plurality of hook holes 110c, into which the conductive wire 120 is inserted, are formed during fabrication of the pad 110.

Such formation of the hook holes 110c may comprise emptying a part corresponding to each hook hole during fabrication of the pad 110 or puncturing a part for each hook hole after completing the pad 110.

Hereinafter, an electric conduction pad according to each of fifth to seventh embodiments so as to accomplish the second object of the present invention will be described in detail.

FIG. 11 is a schematic view illustrating an electric conduction pad according to a fifth embodiment of the present invention, and FIG. 12 is a cross-sectional view taken along lines A-A shown in FIG. 11.

As shown in FIGS. 11 and 12, an electric conduction pad 200 according to the present invention is formed in a band shape by comprising a plurality of elastic wires 210, a conductive wire 220 woven to the elastic wires 210, and a protective fiber yarn 230.

The elastic wires 210 are aligned in a length direction, using a stretchable linear element, and materials of the elastic wire 210 are not particularly restricted if they are elongated in the length direction when tension is applied thereto. In the inventive embodiments, a spandex yarn with excellent elasticity and strength is used.

The conductive wire 220 is woven and aligned on the elastic wires 210 in a zig-zag pattern to pass electric current supplied from a power source or emit heat by the same, and at least one conductive wire may be used.

More particularly, the conductive wire 220 may comprise a power supply cable (a low resistance wire) passing electric current supplied from a power supply unit or otherwise, a heating wire (a high resistance wire) to emit resistant heat by power supplied from the poser supply unit. The conductive wire 220 may have the power supply cable or the heating wire alone or a combination thereof according to use and/or purpose of the conduction pad 200.

The conductive wire 220 may be fabricated using various wire materials without particular restriction so far as they enable passage of electric current or heat generation. For instance, as shown in FIG. 12, multiple strands of conductive cords 221, each comprising Cu micro-wire 221a (Cu wire having a diameter in micrometer unit) coated with an insulation layer 221b, are bound together to form the conductive wire.

Otherwise, the conductive wire 220 may comprise a conductive cord made of a linear element, an insulation film coated on an outer side of the conductive cord and a skin layer made of fiber yarn to cover the insulation film, although not shown in the drawings. Here, the skin layer is formed by knitting or weaving a plurality of fiber yarns around an outer side of the insulation film. The conductive cord may comprise any one selected from electrically conductive wire materials such as carbon fibers, single-stranded metal wires, combined metal micro-wires, fiber yarns containing conductive materials, etc.

The protective fiber yarn 230 is adjacent to the conductive wire 220, aligned in a zig-zag pattern and woven to the elastic wire 210. Since the protective fiber yarn is aligned in a zig-zag pattern and stretched against tension applied in a length direction, the protective fiber yarn may comprise typical fiber yarns such as natural fiber yarns, synthetic fiber yarns, etc. The protective fiber yarn 230 may include at least one anion generating material selected from tourmaline, chitosan powder, tourmaline powder, loess powder, etc. and also contain a sterile material selected from silver particles, charcoal powder, aromatic materials such as agalloch, etc.

As shown in FIG. 12, it is significant that the protective fiber yarn 230 comprises a fiber yarn having a diameter ‘D’ larger than a diameter ‘d’ of the conductive wire 220. If the protective fiber yarn 230 consists of a fiber yarn having the larger diameter ‘D’ than the diameter ‘d’ of the conductive wire 220, the protective fiber yarn 230 first contacts a subject while rubbing against or being in contact with the same when the conduction pad 200 is attached to a garment and used, whereas the conductive wire 220 does not contact the subject. Therefore, the conductive wire 220 may be protected from repeated contact and friction.

As described above, alignment of the conductive wire 220 and the protective fiber yarn 230 entirely has a zig-zag pattern and may have, in detail, a wave form such as sign wave, pulse wave, etc.

Although not shown in FIG. 11, a shape memory alloy yarn and/or optical fiber yarn in contact with the conductive wire 220 or the protective fiber yarn 230, which is aligned in a zig-zag pattern, and woven to the elastic wire, may be additionally included.

As such, if the shape memory alloy yarn to be modified into a morphology, which was inputted in the alloy, at a pre-determined temperature is added to the conduction pad, the conductive wire is duly modified into the inputted morphology when a temperature reaches the pre-determined level, in turn efficiently heating a specific part of the conduction pad. On the other hand, if the optical fiber yarn is added to the conduction pad, light may be emitted into a specific part to induce esthetic sense or sterilize the specific part.

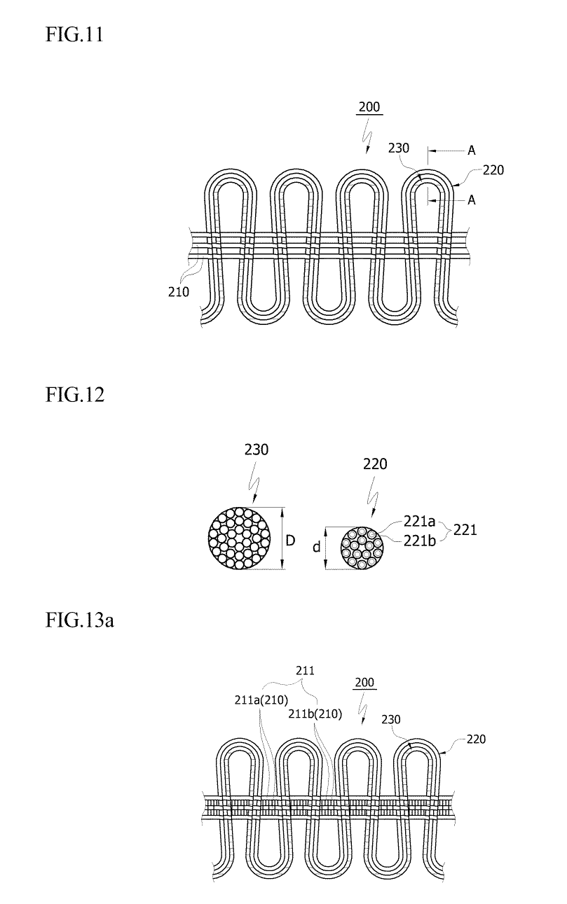

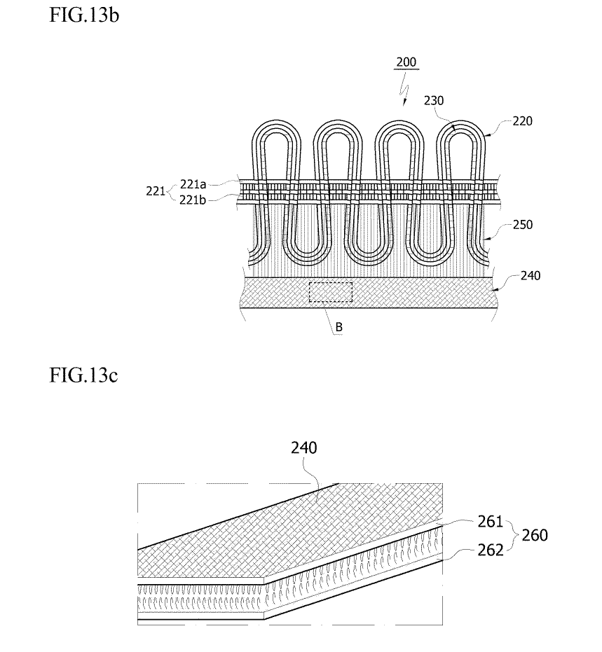

FIG. 13a is a plan view illustrating an electric conduction pad according to a fifth embodiment of the present invention.

Referring to FIG. 13a, the conduction pad 200 according to the fifth embodiment comprises a band type body 211 formed by weaving elastic wires 210 as wefts 211a and warps 211b and a conductive wire 220 and a protective fiber yarn 230 provided and woven together with the band body 211 during formation of the band body 211. Here, the band body 211 is approximately woven into a lattice pattern.

If the band body 211 is formed using the elastic wires 210 as the weft and warp, the conduction pad has elasticity in a length or width direction when tension is applied. Although the conductive wire 220 consists of metal micro-wires without elasticity, it is aligned in a zig-zag pattern and has flexibility so that the conductive wire may not be damaged or fractured by tensile force but become stretchable, thus embodying inherent passage of electric current (in case of a power supply cable) or heating performance (in case of a heating wire).

FIG. 13b illustrates one modification of the electric conduction pad according to the fifth embodiment of the present invention. Referring to this figure, the conduction pad 200 has an extended pad part 240 at a lower side thereof, which is woven using a linear element stretchable in a length direction to have a desired width. Such an extended pad part 240 may also be placed on an upper side of the conduction pad, although not shown in the figure.

The conduction pad also has a stretchable connection part 250 which is combined in a width direction by an elastic linear element so as to leave a constant space between the band body 211 and the extended pad part 240.

The linear element for forming the extended pad part 240 is preferably a spandex yarn having high elasticity and strength among commercially available fiber yarns. The extended pad part 240 may be fabricated using the spandex yarn alone or a combination of the spandex yarn and other general fiber yarns.

The extended pad part 240 may have a configuration enabling the conduction pad 200 of the present invention to be easily mounted on a subject such as a garment. That is, since the extended pad part 240 does not include the conductive wire, significant problems such as damage of the conductive wire 220 are not caused even when the inventive conduction pad 200 is attached, fixed or combined with the subject such as the garment by any conventional method such as backstitching.

FIG. 13c is a partially enlarged perspective view of part B shown in FIG. 13b. Referring to this figure, the conduction pad 200 has an attachment member 260 placed on the extended pad part 240 described in the foregoing modification, which is combined with the subject (not shown, a surface of a garment to which the conduction pad is provided).

The attachment member 260 is not particularly limited so far as one end of the element is bound to the extended pad part 240 and the other end is bound to the subject. In the present modification, the attachment member comprises a female Velcro fastener part 261 (in general, a part formed of multiple loops in the Velcro fastener) placed on the bottom of the extended pad part 240 and a male Velcro fastener part 262 (in general, a protrusion portion in a form of multiple wedges) to be detachable from the female Velcro fastener part 261.

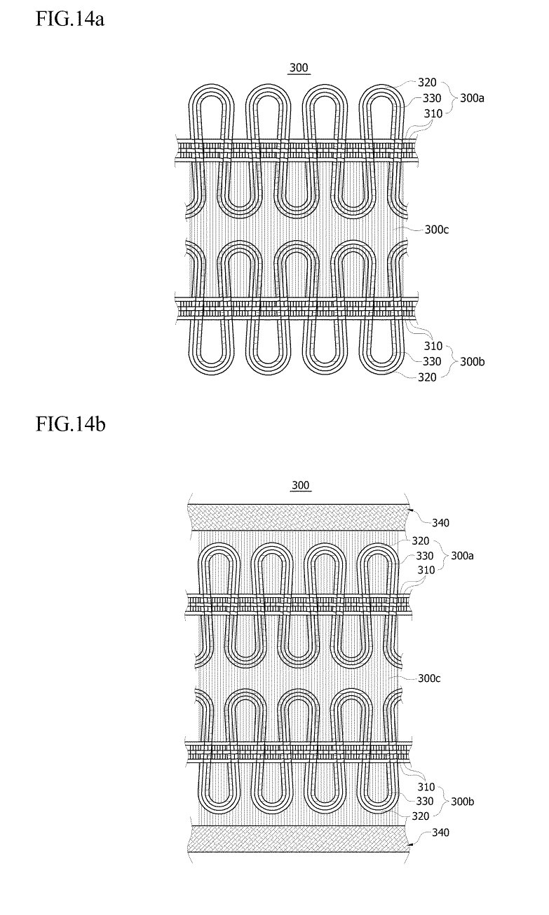

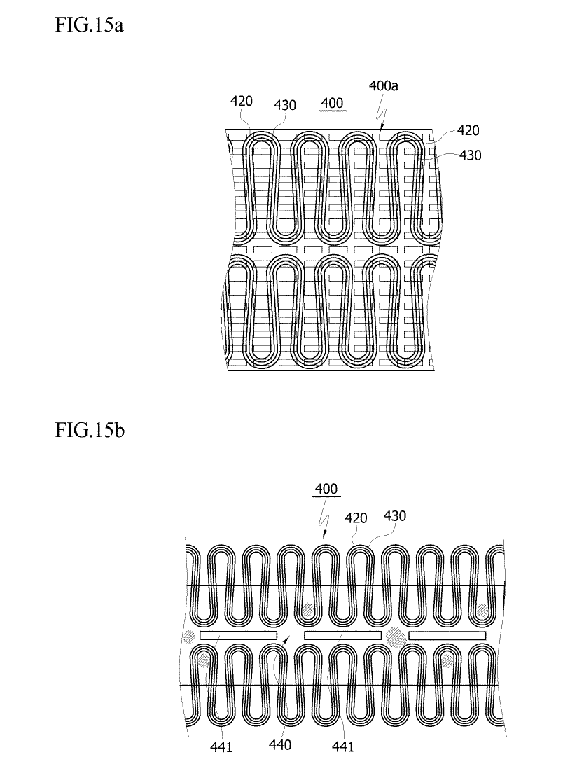

FIG. 14a is a plan view illustrating an electric conduction pad according to a sixth embodiment of the present invention.

Referring to FIG. 14a, the conduction pad 300 according to the sixth embodiment has a multi-structure of at least two pad parts arranged in parallel above and below, wherein each pad part comprises an elastic wire 310, a conductive wire 320 and a protective fiber yarn 330.

For instance, the conduction pad 300 includes: an upper pad part 300a fabricated in a band form by comprising multiple elastic wires 310, a conductive wire 320 and a protective fiber yarn 330; a lower pad part 300b fabricated in a band form by comprising multiple elastic wires 310, a conductive wire 320 and a protective fiber yarn 330; and a stretchable connection part 300c connected between the upper pad part 300a and the lower pad part 300b by an elastic linear element, wherein the upper pad part and the lower pad part are aligned in parallel and apart from each other.

As such, since the upper and lower pad parts 300a and 300b are placed upside and downside of the stretchable connection part 300c, respectively, an electric conduction pad applicable to a wider area may be manufactured. Even when tension is applied in a width direction to the conduction pad 300, the stretchable connection part 300c is elongated in response to the tension. As a result, the upper and lower pad parts 300a and 300b may endure the tension while maintaining their positions at fixed sites thereof without considerable deformation.

FIG. 14b illustrates one modification of the electric conduction pad according to the sixth embodiment of the present invention. Referring to this figure, the conduction pad 300 has extended pad parts 340 at the top of the upper pad part 300a and the bottom of the lower pad part 300b, respectively, which are woven using a linear element stretchable in a length direction to have a desired width.

Similar to the fifth embodiment described above, each of the extended pad parts 340 may be fabricated using a spandex yarn alone or a combination of the spandex yarn with other general fiber yarns and enable the conduction pad 300 to be easily attached to a subject such as a garment without damage thereto.

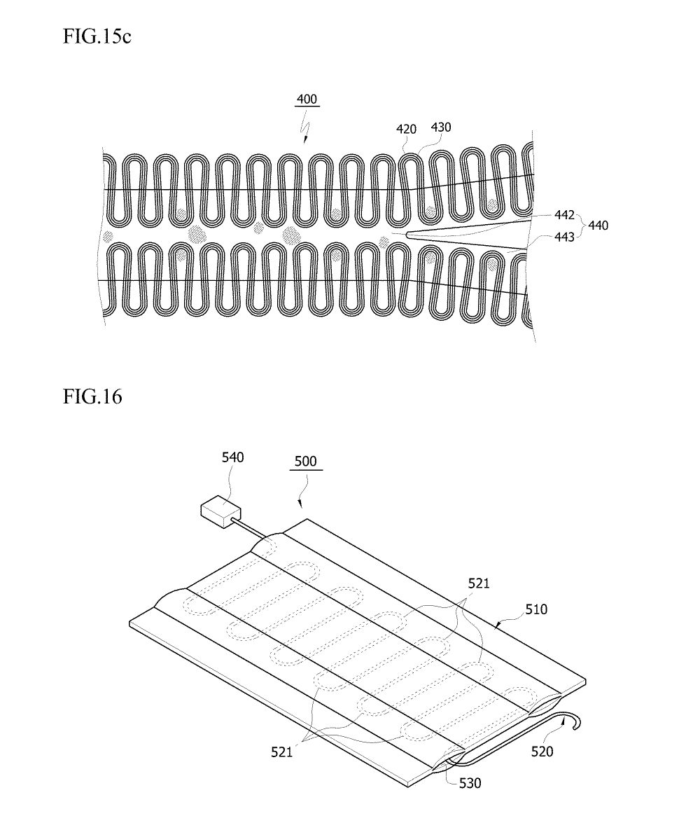

FIG. 15a is a plan view illustrating an electric conduction pad according to a seventh embodiment of the present invention.

The conduction pad 400 according to the seventh embodiment comprises a band type single body 400a, multiple conductive wires 420 woven in a zig-zag pattern and multiple protective fiber yarns 430, wherein the conductive wires 420 and the protective fiber yarns 430 are aligned in parallel above and below in the band body. That is, the conduction pad is fabricated in a band form using multiple elastic wires (used for forming the band body, not shown in FIG. 15a) in addition to the conductive wires 420 woven to the elastic wires as well as the protective fiber yarns 430. In this case, as shown in FIG. 15a, the elastic wires are used as wefts and warps to weave the band type body 400a having multiple holes and the conductive wires 420 and the protective fiber yarns 430, which were woven in a zig-zag pattern, are aligned above and below in the band body 400a.

The foregoing fabricated conduction pad 400 has a planar structure, thus exhibiting excellent effects of contact to a subject and sufficient ventilation because of multiple holes.

FIG. 15b illustrates one modification of the electric conduction pad according to the seventh embodiment of the present invention. Referring to this figure, the conduction pad 400 has a band type body 440 woven by an elastic wire, and multiple holes 441 formed on the band body in a length direction at a constant interval. Each hole 441 is a slot hole having a size sufficient to insert a button into the same. Therefore, after fixing the button (not shown) to a subject (not shown), the conduction pad 400 may be mounted on the subject by inserting the button into the hole 441 and coupling the same to the pad.

FIG. 15c illustrates another modification of the electric conduction pad according to the seventh embodiment of the present invention. Referring to this figure, the conduction pad 400 has a band type body 440 woven using an elastic wire. The band body 440 comprises a wide part 442 having a large width and multiple narrow parts 443 having a small width, which are branched from the wide part 442.

The narrow part 443 includes at least one conductive wire 420 and at least one protective fiber yarn 430 connected to the wide part 442. For this purpose, the wide part 442 may have plural conductive wires 420 and protective fiber yarns 430 at least corresponding to the number of the narrow parts 443.

Although FIG. 15c shows two strands of narrow parts 443 branched from the wide part 442, the number of the narrow parts 443 is not particularly limited and multiple strands of narrow parts may be used according to uses and purposes thereof.

The conduction pad 400 having the wide part 442 and the narrow parts 443 as described above, may be an electric conduction pad requiring elasticity and used for a power supply cable of a particular device or article, which divides a power supply into several ones and provides the divided power supplies to multiple demanding sides. Otherwise, the conduction pad may be a heating conduction pad for a particular device or article, which divides a single power supply into several ones and should generate heat.

For instance, when the conduction pad 400 formed of heating wires according to the present embodiment is applied to a pair of gloves, the conduction wires should be spread from the palm of the hand to every finger. Therefore, the conduction pad may have five strands of narrow parts 443.

FIG. 16 is a perspective view explaining the technical concept of an electric conduction pad according to an eighth embodiment of the present invention. The eighth embodiment is an exemplary embodiment to easily accomplish a third object of the present invention.

As shown in FIG. 16, the conduction pad 500 according to the present invention comprises a planar base 510 woven using fiber yarns and at least one conductive wire 520 woven in a zig-zag pattern on the planar base 510. Inside a part at which both curved sides 521 of the conductive wire 520 are positioned, a flow space 530 is placed and the curved parts 521 are flowing through the flow space.

The planar base 510 is not particularly restricted if it has a planar structure. However, so as to ensure sufficient range of motion and favorable wearing sensation, the planar base is preferably stretchable. For instance, the planar base 510 may be formed into a stretchable pad or fabricated by weaving or knitting fiber yarns.

The conduction pad 500 of the present invention may be variously modified in aspects of use and purpose. For example, in consideration of durability, workability and/or improved wearing sensation, a thin film type resin layer (not shown) may be further applied to either face or both faces of the planar base 510.

The planar base 510 may also include an additional pad layer (not shown) which is prepared on either face or both faces of the base, so as to enable cushioning or heat insulation effects. For example, such an additional pad layer may comprise a sponge type cushion pad or a fabric pad.

Although not specifically illustrated in the drawings, the inventive conduction pad 500 may have a multi-layered structure comprising multiple layers formed by repeatedly laminating the planar base 510 above and below. The planar base including the conductive wire 520 may also be formed into a multi-layered configuration. As described below, when wefts and warps for formation of the planar base 510 are prepared using high strength fiber yarns such as carbon yarns, ceramic fiber yarns, Kevlar yarns, etc., the conduction pad woven using such wefts and warps is lightweight and has high strength, thereby being efficiently used as a raw material or fabric for bulletproof vest, anti-stab clothes or smart military uniform.

The conductive wire 520 is not particularly limited but selectively provided if it enables passage of electric current. The conductive wire may be a power supply cable (a low resistance wire) passing electric current supplied from a power supply unit or a heating wire (a high resistance wire) to emit resistant heat. The conductive wire 520 may have the power supply cable or the heating wire alone or a combination thereof according to use and/or purpose of the same.

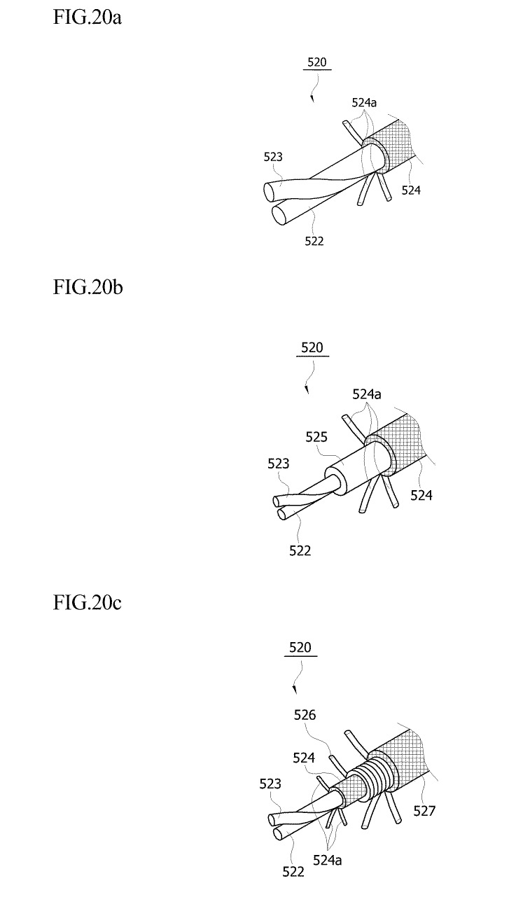

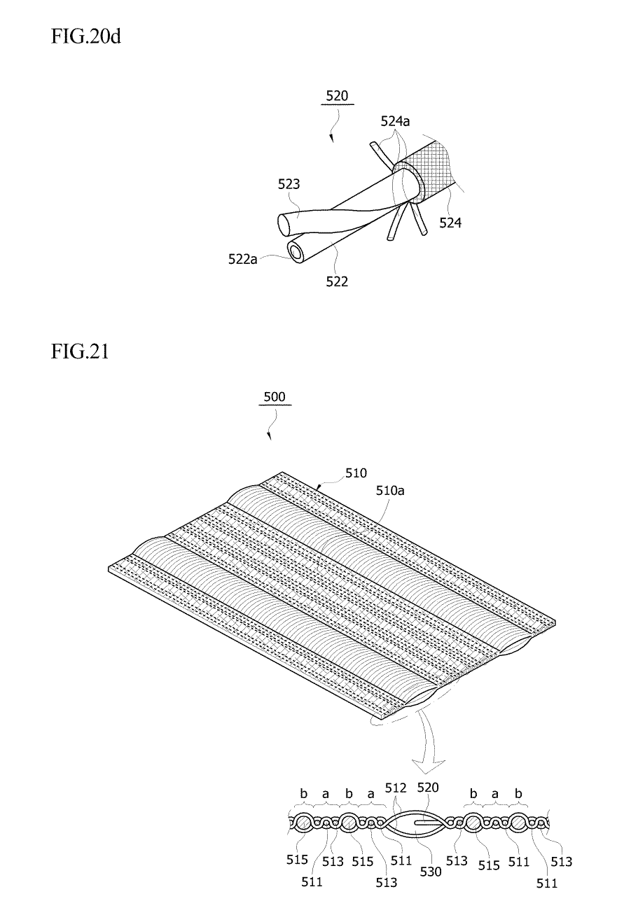

The conductive wire 520 may comprise any one selected from an elastic conductive cord elongated in response to tension or a non-elastic conductive cord such as a typical Cu micro-wire (a Cu wire having a diameter of several tens to several hundreds of micrometers). However, even if the conductive wire 520 in the present embodiment is a non-elastic conductive cord, the conductive cord is aligned in a zig-zag pattern to have elongation in response to tension. Therefore, for such a non-elastic conductive cord, the following description will be given. For instance, as shown in the following FIG. 20a, multiple strands of conductive yarns 522, wherein each conductive yarn is formed of a metal micro-yarn and an insulation film coated thereon, are bound together and used.

The foregoing non-elastic conductive cord may comprise at least one selected from electrically conductive wire materials such as carbon fiber yarns, single-stranded metal wires, fiber yarns containing conductive materials, etc.

Moreover, the conductive wire 520 may fabricated by aligning the non-elastic cord in any one wave structure selected from sine wave, cosine wave, pulse wave (rectangular wave, triangular wave, half sine wave, Gaussian wave, etc.), saw-tooth wave, and so forth. As shown in FIG. 16, the present embodiment adopts alignment of the non-elastic cord to be repeated up and down in a U shape.

A terminal unit 540 connected to the conductive wire 520 and electrically connected to an external power supply unit is placed on either side or both sides of the planar base 510.

Although not specifically illustrated in FIG. 16, the inventive conduction pad 500 may further include a power supply (not shown) such as a battery, a temperature sensor (not shown) to detect a temperature of the planar base 510, and a controller (not shown) comparing the detected temperature with a pre-determined temperature on the basis of detected signals provided from the temperature sensor, so as to control operation of the power supply.

Furthermore, the planar base 510 may further include at least one selected from; an low frequency (LF) generator having an LF electrode to output a low frequency wave; an LED lamp to radiate medical far-infrared rays or UV rays for sterilization; a metering device for measurement of human signals such as a blood sugar meter or a blood pressure gauge; and a thermal module, a charging module, a communication module, etc., which is electrically connected to the conductive wire.

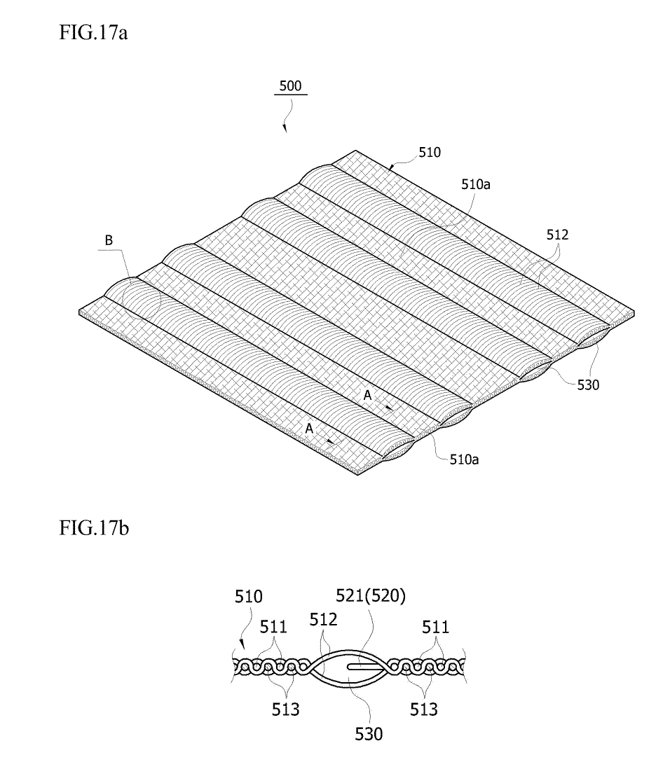

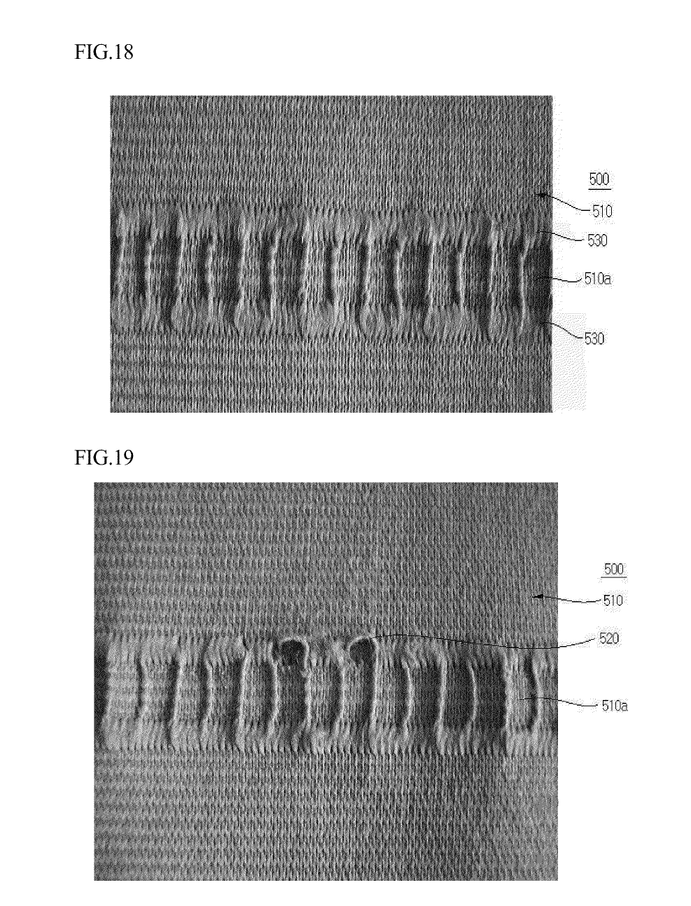

FIG. 17a is a perspective view illustrating an electric conduction pad according to an eighth embodiment of the present invention. FIG. 17b is a schematic cross-sectional view taken along lines A-A shown in FIG. 17a, so as to illustrate the conduction pad of the eighth embodiment of the present invention. FIG. 18 is a plan photograph practically showing the conduction pad of the eighth embodiment of the present invention. FIG. 19 is a partially cut-away plan photograph practically showing main parts of the conduction pad shown in FIG. 18. More particularly, FIG. 19 shows a part of the conduction pad by partially cutting a top face of the flow space 530 so as to expose the conductive wire 520 inside the flow space 530.

Referring to FIGS. 17a to 19, the conduction pad 500 according to the eighth embodiment of the present invention comprises a planar base 510 having the flow space 530, and a conductive wire 520 placed on the planar base 510. The planar base 510 is fabricated by weaving or knitting natural or synthetic fiber yarns as wefts 511 and warps 512, wherein an elastic wire 513 is added as another weft to endow elasticity to the base.

The flow space 530 may be formed in various shapes using the wefts 511 and/or warps 512 during fabrication of the planar base 520. Preferably, as shown in FIGS. 17a to 19, if the wefts 511 are not provided to a site corresponding to a curved part 521 during fabrication of the planar base 510, the warps 512 only are provided upside and downside of the curved part, in turn forming the flow space 530.

More particularly, the planar base 510 is fabricated using fiber yarns as the wefts 511 and warps 512. Multiple strands of the elastic wire 513 such as the spandex yarn are additionally used as another weft 511 so as to induce elongation in a weft direction, that is, a length direction of the planar base 510.

The planar base 510 has a stretchable connection part 510a woven in a transverse direction at a part between both curved sides 521 of the conductive wire 520. Such a stretchable connection part 510a further includes the elastic wire 513 as another weft such as a spandex yarn, during fabrication of the planar base using the wefts 511 and warps 512, as shown in FIG. 17a, thus exhibiting elasticity.

When the conductive wire 520 is formed as a heating wire, the wefts 511 and warps 512 used for fabrication of the planar base 510 are prepared using a wire containing conductive material, so as to efficiently transfer the emitted light from the heating wire. For instance, the conductive wire may be fabricated by adding the conductive material selected from metal nanoparticles, metal oxides and metal oxide particles, which have thermal conduction properties, to the fiber yarn or by adding at least one selected from metal nanoparticles, metal oxides and metal oxide particles to a polymer selected from polyester, polyethylene terephthalate or a copolymer thereof, and then, forming the mixture into the conductive wire as a final product.

As shown in FIG. 16, although the conduction pad 500 has a fabric-like appearance with a longer length compared to a width, however, such an appearance is not particularly limited. That is, a method for fabrication of the planar base 510 or a size (width and length), thickness and/or shape of the same may be varied to produce different types of the base. For instance, if the inventive conduction pad is applied to raw materials for smart clothes, blankets, bed clothes, etc., the conduction pad may have relatively large size and width. On the other hand, for application of medical or health goods such as a health band, a belt, an inner sole, etc., a conduction pad with relatively a small size may be produced.

As shown in FIG. 16, the conductive wire 520 is woven in a zig-zag pattern on the planar base 510. As shown in FIG. 17b, the curved part 521 is placed in the flow space 530. Since the curved part 520 is present in the flow space 530 which is formed inside the wefts 512 aligned above and below, a sufficient space for motion is present without interference even when the curved part is contracted and expanded by tension, thereby ensuring favorable elongation of the conduction pad 500 without damage of the conductive wire 520.

FIG. 20a is a perspective view showing a first example of a conductive wire applied to the electric conduction pad according to the eighth embodiment of the present invention. As shown in this figure, the conductive wire 520 comprises: at least one central yarn 522 placed in the internal center; at least one conductive yarn 523 which is woven and insulation-coated on an outer side of the central yarn 522; and a skin layer 524 formed around an outer side of the conductive wire 523.

The central yarn 522 may comprise aramid fibers, carbon fiber yarns, ceramic fiber yarns, etc. However, a high tensile strength fiber yarn such as Kevlar yarn well known in the art is preferably used. The conductive yarn 523 may be selected from metal yarns comprising a stainless wire, a titanium wire or a copper wire, which has a diameter of several tens to several hundreds of micrometers, and an insulation film to cover the same. The skin layer 524 is formed by weaving multiple strands of fiber yarns 524a around the conductive yarn 523.

Moreover, the conductive yarn 523 woven on the central yarn 522 has a larger formation length per unit length than the fiber yarns used for formation of the skin layer 524 (by increasing the number of winding the conductive yarn 523, compared to the fiber yarn). As such, if a length of the conductive yarn 523 is extended, the fiber yarn 524a is firstly elongated lengthwise when tension is applied to the conductive wire 520, whereas the conductive yarn inside the fiber yarn cannot be fully spread. Therefore, the skin layer 524 functions as an elongation length adjusting line (serving as a stopping).

The conductive yarn 523 may be combined with a linear magnetic wire (not specifically illustrated in the figure) that is formed using a polymer including permanent magnetic powder. Since the magnetic wire has magnetic properties, inherent features of a magnet may advantageously influence the human body when it is employed to manufacture a health (stomach) band or a garment.

FIG. 20b is a perspective view showing a second example of a conductive wire applied to the electric conduction pad according to the eighth embodiment of the present invention. As shown in this figure, the conductive wire 520 has a slide-coating layer 525 so as to minimize friction between the conductive wire 520 and an inner surface of the skin layer 524 and independently vibrate the conductive wire 520 when tension is applied to the conductive yarn 523. Such a slide-coating layer 525 comprises a resin layer prepared by applying a resin having a low friction coefficient to an outer side of the conductive yarn 523 and curing the coated yarn.

If the conductive wire 520 has the slide-coating layer 525, the skin layer 524 covering the outer side of the conductive yarn 523 is woven and fixed to the wefts 511 and warps 512 used for fabrication of the planar base 510, even when the planar base 510 is contracted and expanded and the conductive wire 520 receives such contraction and expansion during use of the conduction pad 500, whereas the conductive yarn 523 can move independent of the skin layer 524. Accordingly, the conductive yarn is not influenced by load but independently moves, in turn preventing damage thereof while improving durability of the conduction pad.

In addition, so as to ensure more stable elasticity, the conductive wire 520 may have an alternative structure characterized in that an elastic wire such as a spandex yarn is used as the central yarn 522 and placed in the internal center, at least one conductive yarn is woven and insulation-coated on an outer side of the elastic wire, and a skin layer is formed over the conductive yarn (since an appearance of the foregoing conductive wire is substantially similar to that shown in FIG. 20a, a figure of the same is not enclosed). In this case, the conductive wire 520 is entirely stretchable, thus efficiently preventing damage of the conductive yarn placed therein.

FIG. 20c is a perspective view showing a third example of a conductive wire applied to the electric conduction pad according to the eighth embodiment of the present invention. As shown in this figure, the conductive wire 520 is fabricated by weaving the conductive yarn 523 and the skin layer 524 in order over an outer side of the central yarn 522, as described above, wherein the central yarn 522 is made of an elastic wire and a hollow 522a is formed inside the elastic wire. Such a hollow 522a can reduce a cross-sectional area of the central yarn, thus improving elongation in response to tension. An air layer is formed inside the hollow 522a and, if a heating wire is used for formation of the conductive wire 520, emitted heat may be retained, in turn enhancing energy efficiency.

Moreover, the conductive wire 520 may contain a conductive solution (not shown) inside the hollow 522a. Such a conductive solution is a sol type solution including a conductive polymer material which is prepared by adding a water-soluble polyaniline solution or polymer solution to a conductive polymer material consisting of metal nanoparticles, metal oxides, metal oxide particles, etc.

FIG. 20d is a perspective view showing a fourth example of a conductive wire applied to the electric conduction pad according to the eighth embodiment of the present invention. As shown in this figure, the conductive wire 520 comprises at least one central yarn 522 placed in the internal center, at least one conductive yarn 523 woven and insulation-coated on an outer side of the central yarn 522, a skin layer 524 formed around an outer side of the conductive yarn 523, at least a second conductive yarn 526 woven and insulation-coated on an outer side of the skin layer 524, and a second skin layer 527 formed around an outer side of the second conductive yarn 526.

Since the fabricated conductive wire 520 has the conductive yarn 523 and the second conductive yarn 526, a single conductive wire may be formed into a power supply cable having bipolar properties (+, −). Accordingly, the power supply cable for the conduction pad 500 of the present invention may be simply fabricated.

FIG. 21 is a perspective view illustrating a first modification of the electric conduction pad according to the eighth embodiment of the present invention, wherein an enlarged part schematically shows a cross-section of part C.

Referring to FIG. 21, the planar base 510 includes a plurality of wires 515 for forming valleys placed in a weft direction at a constant interval so as to form the valleys ‘a’ and peaks ‘b’ on the surface and rear face of the base.

For this purpose, the wires 515 are fabricated using a wire material that has a diameter larger than those of the wefts 511, warps 512 and elastic wire 513, and exhibits sufficient elasticity and flexibility. For instance, the valley forming wire 515 may be fabricated using a spandex yarn having hollows or an elastic wire material.

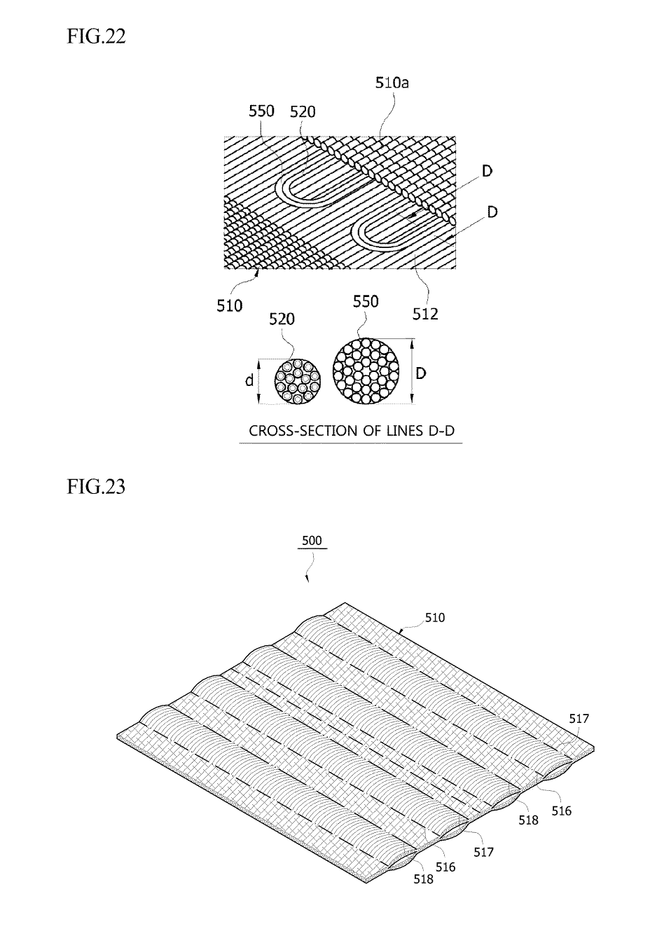

FIG. 22 is a perspective view illustrating a second modification of the electric conduction pad according to the eighth embodiment of the present invention wherein an enlarge part schematically shows a cross-section of part D-D.

Referring to FIG. 22, the conduction pad 500 further includes a protective fiber yarn 550 which is adjacent and woven to the conductive wire 520 bound on the planar base 510.

The protective fiber yarn 550 is adjacent to the conductive wire 520 and woven in a zig-zag pattern. Because of such a zig-zag pattern, the protective fiber yarn is elongated in response to tension in a length direction. Therefore, the protective fiber yarn may be prepared using typical fiber yarns including natural fiber yarns, synthetic fiber yarns, etc. The protective fiber yarn 550 may contain at least one selected from anion generating materials such as tourmaline, chitosan powder, tourmaline powder, loess powder, etc. The protective fiber yarn may also contain sterile materials such as silver particles or charcoal powder and/or aromatic materials such as agalloch.

As shown in the enlarged FIG. 22, it is significant that the protective fiber yarn 550 is made of a fiber yarn having a diameter ‘D’ larger than a diameter ‘ d’ of the conductive wire 520. When the protective fiber yarn 550 is fabricated using the fiber yarn with the larger diameter ‘D’ than the diameter ‘d’ of the conductive wire 520, the protective fiber yarn 550 first contacts a subject while rubbing against or being in contact with the same when the conduction pad 500 is attached to a garment and used, whereas the conductive wire 520 does not contact the subject. Therefore, the conductive wire 520 may be protected from repeated contact and friction.

The conduction pad 500 may further include a shape memory wire (not shown) which is adjacent and woven to the conductive wire 520 bound on the planar base 510. That is, the shape memory wire is adjacent to the conductive wire 520 and woven in a zig-zag pattern, which is substantially similar to the morphology shown in FIG. 22 (by aligning the shape memory wire, instead of the protective fiber yarn). The foregoing shape memory wire is fabricated by forming a polymeric shape memory resin or a shape memory alloy, which has shape memory features to be modified into a specific morphology at a pre-determined temperature, into a wire shape and applying a polymer resin to the shaped wire to produce an insulation coating layer.

Such a polymer resin having shape memory features may include general materials well known in the art, for example: a shape recovery resin such as trans-polyisoprene that uses a melting point of crystals as a shape recovery temperature and cross-linkages of chains as a stationary phase; a shape memory resin such as polynorbornene that uses a glass transition temperature as a shape recovery temperature and physical cohesion of chains as a stationary phase; polyaliphatic ester-polyamide block copolymer, so forth.

Meanwhile, the conduction pad 500 may have an optical fiber yarn (not shown, which is aligned instead of the protective fiber yarn 550) woven and aligned on the conductive wire 520 in a zig-zag pattern, which is substantially similar to the foregoing shape memory wire.

As such, if the conduction pad 500 has the optical fiber yarn, the conduction pad may not only be used in data transmission but also have advantages in that light may be emitted into a specific part to induce esthetic sense and/or sterilize the specific part.

Additionally, the planar base 510 may further include an electromagnetic shielding wire (not shown) with electromagnetic shield properties so as to block electromagnetic wave radiated from the conductive wire 520. The electromagnetic shielding wire may be prepared using a metal-plated fiber yarn, a fiber yarn containing metal powder, a micro-metal yarn or a ceramic fiber yarn.

FIG. 23 is a perspective view illustrating a third modification of the electric conduction pad according to the eighth embodiment of the present invention. As shown in FIG. 23, the conduction pad 500 may have an alternative structure in that a shape memory alloy yarn 516, an optical fiber yarn 517 or an electromagnetic shielding wire 518 is aligned in a weft or warp direction of the planar base 510, instead of the zig-zag alignment of the foregoing elements adjacent to the conductive wire 520. Here, the shape memory alloy yarn 516, the optical fiber yarn 517 and the electromagnetic shielding wire 518 are wound in coil shape to have elasticity.

The planar base 500 may include a linear light emitting wire (not shown) to be turned on by an applied power source. The linear light emitting wire may be formed using an organic electroluminescence (EL) or inorganic EL.

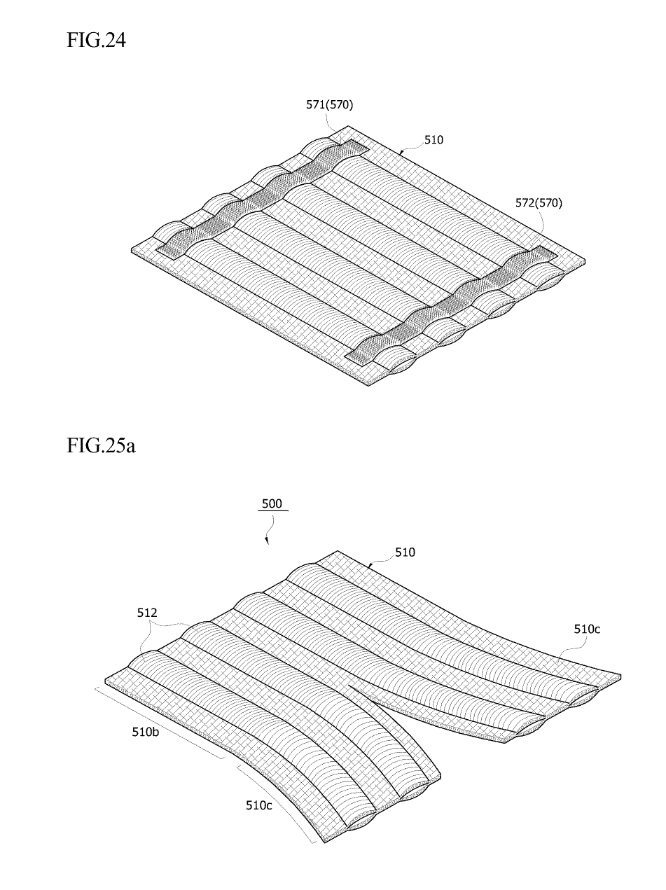

FIG. 24 is a perspective view illustrating a fourth modification of the electric conduction pad according to eighth embodiment of the present invention. As shown in this figure, the conduction pad has a connector 570 to connect together both ends of the pad or to connect the conduction pad to a subject (not shown, a surface of a pre-determined part of a garment to which the conduction pad is provided).

The connector 570 is not particularly limited if one side of the connector is bound to the planar base 510 and the other side is bound to the subject and may include, for example, a female/male Velcro fastener, a female/male one-touch type button, a zipper type fastener, a female/male coupling ring, and the like. In the present embodiment, the connector comprises a female Velcro fastener part 571 (in general, a planar part having multiple loops in a typical Velcro fastener) placed on the bottom of the planar base 510 and a male Velcro fastener part 572 (in general, a planar part having multiple wedges in a typical Velcro fastener) to be detachable from the female Velcro part 571.

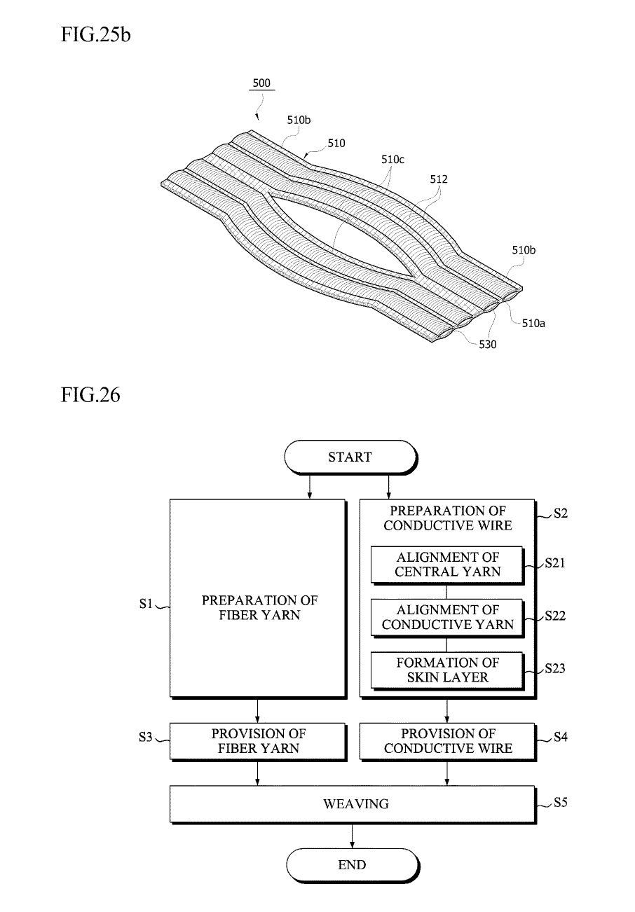

FIGS. 25a and 25b are perspective views illustrating a fifth modification of the electric conduction pad according to the eighth embodiment of the present invention. Referring to FIG. 25a, the conduction pad 500 comprises a planar base 510 having desired width and length and a plurality of conductive wires 520 woven in a zig-zag pattern on the planar base. The planar base 510 has a wide part 510b having a large width and multiple narrow parts 510c having a small width, which are branched from the wide part 510b.

In this regard, each of the narrow parts 510c has at least one conductive wire 520 connected to the wide part 510b. For this purpose, the wide part 510b has plural conductive wires 520 at least corresponding to the number of the narrow parts 510c.

Although FIG. 25a shows two strands of narrow parts 510c branched from the wide part 510b, the number of the narrow parts 510c is not particularly limited and multiple strands of narrow parts may be used according to uses and purposes thereof.

The conduction pad 500 having the wide part 510b and the narrow parts 510c as described above, may be an electric conduction pad 500 requiring elasticity and used for a power supply cable of a particular device or article, which divides a power supply into several ones and provides the divided power supplies to multiple demanding sides. Otherwise, the conduction pad may be a heating conduction pad for a particular device or article, which divides a single power supply into several ones and should generate heat.

For instance, when the conduction pad 500 formed to emit heat according to the present embodiment is applied to a pair of gloves, the conduction wires 520 made of heating wires should be spread from the palm of the hand to every finger. Therefore, the conduction pad may have five strands of narrow parts 510c.

In addition, as shown in FIG. 25b, the narrow parts 510c branched from the wide part 510b may be collected together to form the wide part 510b again.

FIG. 26 is a flow diagram explaining a process of manufacturing the electric conduction pad according to the eighth embodiment of the present invention.

Referring to FIG. 26, the method for manufacturing the electric conduction pad according to the present invention includes fabrication of a fiber yarn and a conductive wire (S1, S2) by preparing a weft 511, a warp 512 and a conductive wire 520. Then, using the weft 511, the warp 512 and the conductive wire 520 provided through multiple processes for provision of the fiber yarn (S3), the conductive wire (S4), the fiber yarn (S3) and the conductive wire (S4), a weaving process (S5) is conducted to manufacture an electric conduction pad 500 comprising a planar base 510 and the conductive wire 520 aligned in a zig-zag pattern on the planar base 510.

The processes for fabrication of the fiber yarn and the conductive wire (S1 and S2) are conducted to prepare the fiber yarn used as the weft and warp, an elastic wire 513 and the conductive wire 520. Firstly, the process for fabrication of the conductive wire (S2) includes: placing a central yarn 522 in the internal center (S21); provision of a conductive yarn by providing at least one insulation-coated conductive yarn 523 over an outer side of the central yarn 522 and weaving the same (S22); and formation of a skin layer by forming the skin layer 524 around an outer side of the conductive yarn 523 (S23), thus producing the conductive wire as shown in FIG. 20a.

Following this, the prepared conductive wire 520, the fiber yarn provided as the weft 511 and warp 512 and the elastic wire (513, a spandex yarn) are wound around feeding rolls (referred to as carrier or reel) and these feeding rolls are ready to conduct a weaving process by loosing one ends of the yarns from the feeding rolls and inserting the loosen yarns into needles of a weaving machine.

The process for fabrication of the conductive wire is conducted after completing alignment of a conductive yarn (S22) and may further include formation of a coating layer comprising use of a raw material such as resin having a low friction coefficient to form a slide-coating layer 525 around an outer side of the conductive yarn 523, as shown in FIG. 20b. According to such formation of the coating layer, even when an external force is applied to the planar base 510 during use of the conduction pad 500 and, therefore, contraction/expansion force is applied to the conductive yarn 523 of the conductive wire 520, the conductive yarn 523 moves independent of the skin layer 524 owing to the slide-coating layer 525, thereby preventing damage of the conductive yarn 523.

The fiber yarn to be used as wefts and warps is fed in the process for provision of the fiber yarn (S3) so as to fabricate the planar base 510 and, according to operation of the weaving machine, the fiber yarn wound around the feeding roll is pulled and fed to weave the wefts and warps.

In the process for provision of the fiber yarn (S3), the elastic wire 513 such as a spandex yarn is also preferably provided as the weft and/or warp, as shown in FIG. 17a, so as to endow elasticity to the woven planar base 510 during the weaving process (S5). In the present embodiment, the elastic wire 513 is provided as the weft 511 to obtain elongation in response to tension applied to the planar base 510.

The process for fabrication of the conductive wire (S4) is to provide at least one conductive wire 520 while feeding and weaving the wefts and warps in a zig-zag pattern on the planar base 510, and is conducted to feed the conductive wire 520 in a zig-zag pattern while pulling the same wound over the feeding roll according to operation of the weaving machine.

The weaving process (S5) is conducted to weave the planar base 510 using the fiber yarn as the weft and warp, the elastic wire and the conductive wire and, at the same time, to form a flow space 530 inside both curved parts 521 of the conductive wire 520, wherein the flow space is prepared for flowing the curved parts therein.

According to the eighth embodiment, the wefts 512 present above and below of the curved part 521 form the flow space 530. For this purpose, if the weft is not fed in a width range of the flow space 530 to the curved part 521 during provision of the fiber yarn (S3), the warp only is used for weaving and forms an empty space therein.

The conduction pad of the present invention may comprise a planar heating body or conductive body having elastic properties fabricated using a conductive wire that has conductive properties without elasticity such as a carbon fiber yarn, a copper wire, etc. Accordingly, using the inventive conduction pad in manufacture of smart clothes requiring a wide range of motion or a heating device, various features such as motion, durability and convenience in use may be remarkably enhanced. Especially, the planar body having the conductive wire may be manufactured by only one weaving process so as to improve productivity and reduce thickness and weight of a product, in turn ensuring favorable wearing sensation and sufficient range of motion. In addition, when the planar base is fabricated into a multi-layered fabric by weaving or knitting a high strength fiber yarn, the fabric may be lightweight while having high strength, thereby being efficiently applied to raw materials for bulletproof vest, anti-stab clothes, smart military uniforms, and so forth.

Although an electric conduction pad and a method for manufacturing the same according to preferred embodiments of the present invention have been described in conjunction with accompanying drawings, it is only illustrative. It will be understood by those skilled in the art that various modifications and equivalents can be made to the present invention. Therefore, the true technical scope of the present invention should be defined by the appended claims.

1. An electric conduction pad, comprising:
a stretchable planar pad; and
at least one conductive wire aligned in a zig-zag pattern on the pad to pass electric current supplied from a power source or emit heat by the same.

2. The electric conduction pad according to claim 1, wherein a static fiber yarn is bound to a part adjacent to both curved sides of the conductive wire which is aligned in a zig-zag pattern on the top of the planar pad, and the conductive wire is combined with the planar pad while pulling the planar pad in a length direction.

3. The electric conduction pad according to claim 1, wherein the conductive wire is aligned in a zig-zag pattern on the top of the planar pad fabricated using wefts and warps, and a part adjacent to both curved sides of the conductive wire is inserted and bound between the wefts and warps of the planar pad.

4. The electric conduction pad according to claim 1, wherein the pad has a bottom fabric part fabricated in a planar shape using wefts and warps and a top fabric part fabricated in a planar shape over the bottom fabric part using wefts and warps, and wherein the conductive wire is placed in a zig-zag pattern on the top of the bottom fabric part, and a part adjacent to both curved sides of the conductive wire is bound by wefts and warps while being interposed between the top fabric part and the bottom fabric part.

5. The electric conduction pad according to claim 1, wherein the pad has a plurality of hook holes formed on the surface of the planar pad by puncturing, and the conductive wire is inserted and bound in a zig-zag pattern into the hook holes.

6. (canceled)

7. (canceled)

8. (canceled)

9. (canceled)

10. (canceled)

11. (canceled)

12. (canceled)

13. The electric conduction pad according to claim 1, wherein the conductive wire comprises:
a conductive cord selected from electrically conductive wire materials such as carbon fiber yarns, metal wires, combined metal micro-wires and fiber yarns containing conductive materials;
an insulation film coated on an outer side of the conductive cord; and
a skin layer formed by knitting a fiber yarn around an outer side of the insulation film including the conductive cord.

14. (canceled)

15. (canceled)

16. A method for manufacturing an electric conduction pad, comprising:
fabricating a planar pad using at least one elastic fiber yarn as wefts and warps; and
providing a conductive wire on the planar pad by aligning the conductive wire in a zig-zag pattern on the top of the planar pad and binding a part, which is adjacent to both curved sides of the conductive wire, to the planar pad.

17. (canceled)

18. (canceled)

19. (canceled)

20. A method for manufacturing an electric conduction pad, comprising:
fabricating a planar pad using at least one elastic fiber yarn as wefts and warps; and
providing a conductive wire on the planar pad by aligning the conductive wire in a zig-zag pattern on the top of the planar pad and inserting a part, which is adjacent to both curved sides of the conductive wire, between the wefts and warps to be bound thereto.

21. (canceled)

22. (canceled)

23. (canceled)

24. (canceled)

25. (canceled)

26. (canceled)

27. (canceled)

28. An electric conduction pad in a band form, comprising:
a plurality of elastic wires aligned in a length direction;
at least one conductive wire woven and aligned in a zig-zag pattern on the elastic wires;
and
a protective fiber yarn woven on the elastic wires such that the protective fiber yarn is aligned in a zig-zag pattern adjacent to the conductive wire.

29. (canceled)

30. (canceled)

31. (canceled)

32. (canceled)

33. (canceled)

34. (canceled)

35. The electric conduction pad according to claim 28, wherein the protective fiber yarn comprises a fiber yarn having an outer diameter larger than that of the conductive wire.

36. (canceled)

37. (canceled)

38. (canceled)

39. An electric conduction pad, comprising:
a base formed in a planar shape; and
at least one conductive wire woven and aligned in a zig-zag pattern on the planar base, wherein the planar base has a flow space inside a part, at which both curved sides of the conductive wire is positioned, so as to flow the curved parts through the flow space.

40. (canceled)

41. (canceled)

42. (canceled)

43. (canceled)

44. (canceled)

45. (canceled)

46. (canceled)

47. The electric conduction pad according to claim 39, wherein the conductive wire includes:
at least one central yarn placed in the internal center;
at least one conductive yarn which is woven on an outer side of the central yarn and insulation-coated on the same; and
a skin layer formed around an outer side of the conductive yarn.

48. (canceled)

49. (canceled)

50. (canceled)

51. (canceled)

52. The electric conduction pad according to claim 39, wherein the conductive wire includes:
at least one central yarn comprising an elastic wire placed in the internal center;
at least one conductive yarn which is woven on an outer side of the central yarn and insulation-coated on the same; and
a skin layer formed around an outer side of the conductive yarn.

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. The electric conduction pad according to claim 39, wherein the flow space is formed using a fiber yarn used for fabrication of the planar base.

66. (canceled)

67. (canceled)

68. The electric conduction pad according to claim 39, wherein the planar base has a wide part with a relatively large width and a plurality of narrow parts with a relatively small width which are branched from the wide part, and the wide part includes plural conductive wires corresponding to at least the number of the narrow parts, so as to provide at least one conductive wire in each of the narrow parts.

69. (canceled)

70. (canceled)

71. The electric conduction pad according to claim 39, further comprising:
a power supply unit to supply power;
a temperature sensor to detect a temperature of the planar base; and
a controller comparing the detected temperature with a pre-determined temperature on the basis of detected signals provided from the temperature sensor, so as to control operation of the power supply unit.

72. (canceled)

73. A method for manufacturing an electric conduction pad, comprising:
providing a fiber yarn as wefts and warps so as to form a planar base;
simultaneously providing at least one conductive wire as well as the wefts and warps to be woven in a zig-zag pattern on the planar base; and
fabricating the planar base using the wefts, warps and conductive wire, which are provided during provision of the fiber yarn and during provision of the conductive wire, respectively, by a weaving process, wherein a flow space is formed inside a part, at which both curved sides of the conductive wire are positioned, during the weaving process so as to flow the curved parts through the flow space.

74. (canceled)

75. (canceled)

76. (canceled)

77. (canceled)

78. The electric conduction pad according to claim 2, wherein the conductive wire comprises:
a conductive cord selected from electrically conductive wire materials such as carbon fiber yarns, metal wires, combined metal micro-wires and fiber yarns containing conductive materials;
an insulation film coated on an outer side of the conductive cord; and
a skin layer formed by knitting a fiber yarn around an outer side of the insulation film including the conductive cord.

79. The electric conduction pad according to claim 3, wherein the conductive wire comprises:
a conductive cord selected from electrically conductive wire materials such as carbon fiber yarns, metal wires, combined metal micro-wires and fiber yarns containing conductive materials;
an insulation film coated on an outer side of the conductive cord; and
a skin layer formed by knitting a fiber yarn around an outer side of the insulation film including the conductive cord.

80. The electric conduction pad according to claim 4, wherein the conductive wire comprises:
a conductive cord selected from electrically conductive wire materials such as carbon fiber yarns, metal wires, combined metal micro-wires and fiber yarns containing conductive materials;
an insulation film coated on an outer side of the conductive cord; and
a skin layer formed by knitting a fiber yarn around an outer side of the insulation film including the conductive cord.

81. The electric conduction pad according to claim 5, wherein the conductive wire comprises:
a conductive cord selected from electrically conductive wire materials such as carbon fiber yarns, metal wires, combined metal micro-wires and fiber yarns containing conductive materials;
an insulation film coated on an outer side of the conductive cord; and
a skin layer formed by knitting a fiber yarn around an outer side of the insulation film including the conductive cord.
